(19) United States
(12) Patent Application Publication
(10) Pub. No.: US 2024/0431193 A1
(43) Pub. Date: Dec. 26, 2024

(54) DISPLAY DEVICE AND METHOD OF FABRICATING DISPLAY DEVICE

(71) Applicant: Samsung Display Co., LTD., Yongin-si (KR)

(72) Inventors: Dan Bi CHOI, Yongin-si (KR); Dong Jo KIM, Yongin-si (KR); Hyun KIM, Yongin-si (KR); Seong Geun WON, Yongin-si (KR); Je Won YOO, Yongin-si (KR); Seung Min LEE, Yongin-si (KR); Souk June HWANG, Yongin-si (KR)

(21) Appl. No.: 18/608,616

(22) Filed: Mar. 18, 2024

(30) Foreign Application Priority Data
Jun. 22, 2023 (KR) 10-2023-0080263

(51) Int. Cl. H10K 77/10; H10K 59/127; H10K 71/80

(52) U.S. Cl. CPC H10K 77/111; H10K 59/127; H10K 71/80

(57) ABSTRACT

Provided are display device and method of fabricating display device. A display device includes a first substrate including a rigid material, and including a first surface, a second surface opposite to the first surface, and a first side surface between the first surface and the second surface, a protective layer on the first surface, a second substrate including a flexible material on the protective layer, and an emission material layer including light-emitting elements on the second substrate.

### CROSS-REFERENCE TO RELATED APPLICATION

The present application claims priority to, and the benefit of, Korean Patent Application No. 10-2023-0080263, filed on Jun. 22, 2023, in the Korean Intellectual Property Office, the entire disclosure of which is incorporated herein by reference.

### BACKGROUND

### 1. Field

The present disclosure relates to a display device, and a method of fabricating the same.

### 2. Description of the Related Art

As the information-oriented society evolves, various demands for display devices are ever increasing. Display devices may be flat panel display devices, such as a liquid-crystal display device, a field emission display device, and a light-emitting display device.

A display device includes a display area where images are displayed, and a non-display area around the display area, for example. Recently, the width of the non-display area is ever decreasing to enable viewers to get more immersed in the contents displayed on the display area, and to increase the aesthetics of the display device.

To reduce the width of a non-display area, a bending area may be formed between a pad area and a display area, and the pad area may be positioned under a display panel when the bending area is bent. To this end, a substrate made of a flexible material that can be bent is used. As the size of the substrate increases, a substrate made of a rigid material may be further included to maintain the shape.

### SUMMARY

Aspects of the present disclosure provide a display device with a non-display area having a reduced width, and a method of fabricating a display device.

Aspects of the present disclosure also provide a display device that does not include an undercut between upper and lower substrates, and a method of fabricating a display device.

It should be noted that aspects of the present disclosure are not limited to the above-mentioned aspect, and that other aspects of the present disclosure will be apparent to those skilled in the art from the following descriptions.

According to an aspect of the present disclosure, there is provided a display device including a first substrate including a rigid material, and including a first surface, a second surface opposite to the first surface, and a first side surface between the first surface and the second surface, a protective layer on the first surface, a second substrate including a flexible material on the protective layer, and an emission material layer including light-emitting elements on the second substrate.

The first side surface may be at an edge in a bending area where the second substrate is bent.

The first substrate might not be in the bending area.

The first substrate may define opening exposing the protective layer in the bending area.

The first side surface may be an inclined surface extending in a direction that is different from a direction in which the first surface extends.

An entirety of the first surface may directly contact the protective layer.

The first surface and the first side surface may directly contact each other.

An inclined surface extending in a direction that is different from directions in which the first surface and the first side surface extend might not be between the first surface and the first side surface.

A boundary where the first side surface meets the protective layer might not overlap with a display area in which the light-emitting elements are located.

The first substrate may include glass, wherein the second substrate includes a polymer resin.

An adhesive strength of the protective layer to the first substrate may be higher than an adhesive strength of the second substrate to the first substrate.

The protective layer may include silicon.

The protective layer may include amorphous silicon or silicon oxide (SiOx).

The protective layer may have a thickness of about 0.1 μm or less.

The second substrate may include a first subsidiary substrate on the protective layer, a barrier layer on the first subsidiary substrate, and a second subsidiary substrate on the barrier layer.

The barrier layer and the protective layer may include a same material.

The protective layer may include a first protective layer including silicon oxide (SiOx) on the first substrate, and a second protective layer including amorphous silicon on the first protective layer.

According to an aspect of the present disclosure, there is provided a method of fabricating a display device, the method including preparing a first mother substrate having a first surface, and a second surface opposite to the first surface, a protective layer on the first surface, a second mother substrate on the protective layer, and a display layer on the second mother substrate, attaching a first protective film on the second surface, removing a portion of the first protective film from a bending area, removing a portion of the first mother substrate from the bending area by spraying an etchant onto the second surface, entirely removing the first protective film on the second surface, and exposing the protective layer by spraying an etchant onto the second surface to reduce a thickness of the first mother substrate.

In the exposing the protective layer, an entirety of the first surface may be in direct contact with the protective layer.

The protective layer may include silicon. According to one or more embodiments of the present disclosure, the width of a non-display area of a display device can be reduced.

According to one or more embodiments of the present disclosure, there is no undercut between upper and lower substrates of a display device.

It should be noted that aspects of the present disclosure are not limited to those described above and other aspects of the present disclosure will be apparent to those skilled in the art from the following descriptions.

### BRIEF DESCRIPTION OF THE DRAWINGS

The above and other aspects of the present disclosure will become more apparent by describing in detail embodiments thereof with reference to the attached drawings, in which:

FIG. 1 is a perspective view showing a display device according to one or more embodiments of the present disclosure.

FIG. 2 is a plan view showing a display panel and driver ICs according to one or more embodiments.

FIG. 3 is a cross-sectional view showing an example of the display area of the display device according to one or more embodiments of the present disclosure.

FIG. 4 is a cross-sectional view taken along the line X1-X1′ in FIG. 1.

FIG. 5 is a cross-sectional view showing the display device according to the one or more embodiments corresponding to FIG. 4 when it is bent.

FIG. 6 is an enlarged view of portion A of FIG. 4.

FIG. 7 is a cross-sectional view schematically showing an existing display device.

FIG. 8 is a cross-sectional view showing the existing display device of FIG. 7 when it is bent.

FIG. 9 is an enlarged, cross-sectional view showing a part of a display device according to one or more other embodiments of the present disclosure.

FIG. 10 is an enlarged cross-sectional view showing a part of a display device according to yet one or more other embodiments of the present disclosure.

FIG. 11 is a flowchart for illustrating a method of fabricating a display device according to one or more embodiments of the present disclosure.

FIG. 12 is a cross-sectional view showing operation S100 of FIG. 11.

FIG. 13 is a cross-sectional view showing operation S200 of FIG. 11.

FIG. 14 is a cross-sectional view showing operation S300 of FIG. 11.

FIG. 15 is a cross-sectional view showing operation S400 of FIG. 11.

FIG. 16 is a cross-sectional view showing operation S500 of FIG. 11.

FIG. 17 is a cross-sectional view showing operation S600 of FIG. 11.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

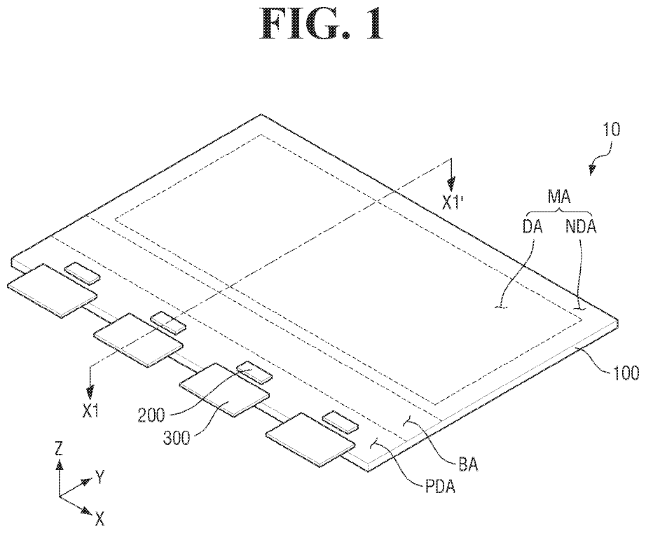

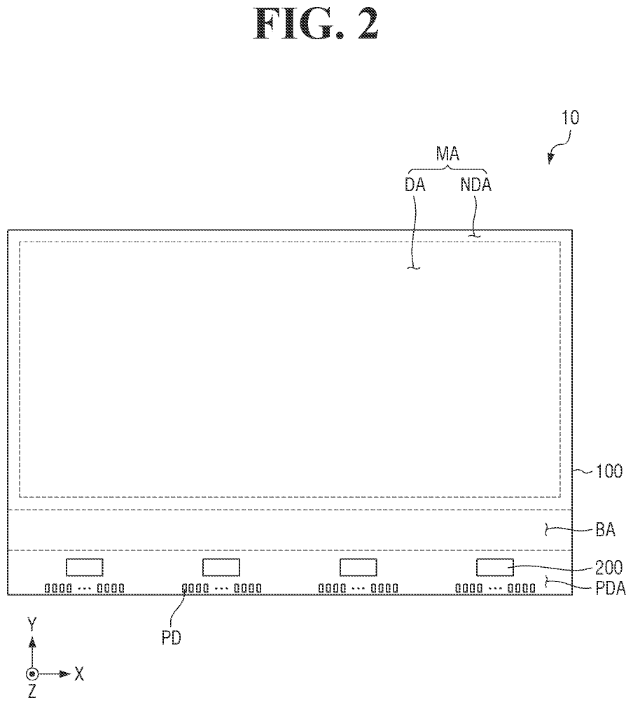

FIG. 1 is a perspective view showing a display device according to one or more embodiments of the present disclosure. FIG. 2 is a plan view showing a display panel and driver ICs according to one or more embodiments.

Referring to FIGS. 1 and 2, a display device 10 according to one or more embodiments of the present disclosure is for displaying moving images or still images. The display device 1 may be used as the display screen of portable electronic devices, such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products, such as a television, a notebook, a monitor, a billboard and the Internet of Things device.

According to one or more embodiments of the present disclosure, the display device 10 may be a light-emitting display device, such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 10. It is, however, to be understood that the present disclosure is not limited thereto.

The display device 10 according to one or more embodiments may include a display panel 100, a driver integrated circuits (ICs) 200, and circuit boards 300.

The display panel 100 may be formed in a rectangular plane having longer sides in a first direction (x-axis direction), and shorter sides in a second direction (y-axis direction) intersecting the first direction (x-axis direction). Each of the corners where the longer side in the first direction (x-axis direction) meets the shorter side in the second direction (y-axis direction) may be formed at a right angle, or may be rounded with a curvature. The shape of the display panel 100 when viewed from the top is not limited to a quadrangular shape, but may be formed in a different polygonal shape, a circular shape, or an elliptical shape.

In the drawings, the first direction (x-axis direction) and the second direction (y-axis direction) intersect each other as the horizontal directions. For example, the first direction (x-axis direction) and the second direction (y-axis direction) may be orthogonal to each other. In addition, the third direction (z-axis direction) may intersect the first direction (x-axis direction) and the second direction (y-axis direction), and may be, for example, a vertical direction orthogonal to the first direction (x-axis direction) and the second direction (y-axis direction). Herein, the side indicated by the arrow of each of the first to third directions (x-axis direction, y-axis direction, and z-axis direction) may be referred to as a first side, while the opposite side may be referred to as a second side.

The display panel 100 may be formed flat, but the present disclosure is not limited thereto. For example, the display panel 100 may be formed at left and right ends, and may include a curved portion having a constant curvature or a varying curvature. In addition, the display panel 100 may be flexible so that it can be curved, bent, folded, or rolled.

The display panel 100 may include a main area MA, a bending area BA, and a pad area PDA. The main area MA may include a display area DA where images are displayed, and a non-display area NDA around the display area DA.

The display area DA may occupy most of the area of the display panel 100. The display area DA may be located at the center of display device 100. In the display area DA, pixels each including a plurality of emission areas may display images.

The non-display area NDA may be adjacent to the display area DA. The non-display area NDA may be located on the outer side of the display area DA. The non-display area NDA may surround the display area DA. The non-display area NDA may be defined as the border of the display panel 100.

The bending area BA may be between the display area DA and the pad area PDA in the second direction (y-axis direction). The bending area BA may extend in the first direction (x-axis direction). The bending area BA may be bent to be beneath the display panel 100. When the bending area BA is bent and located under the display panel 100, the plurality of driver ICs 200 and the circuit boards 300 may be located under the display panel 100.

The pad area PDA may be the lower edge area of the display panel 100. In the pad area PDA, display pads PD connected to the circuit boards 300, and first and second driving pads connected to the driver ICs 200 may be located.

In the pad area PDA, display pads DP may be connected to the circuit boards 300. The display pads DP may be located at one edge of the display panel 100. For example, the display pads DP may be located at the lower edge of the display panel 100.

The driving integrated circuits (ICs) 200 may generate data voltages, supply voltages, scan timing signals, etc. The driver ICs 200 may output data voltages, supply voltages, scan timing signals, etc.

The driver ICs 200 may be located in the pad area PDA. The driver ICs 200 may be located between the display pads PD and the display area DA in the non-display area NDA. The driver ICs 200 may be attached to the non-display area NDA of the display panel 100 by a chip-on-glass (COG) technique. Alternatively, the driver ICs 200 may be attached to the circuit boards 300, respectively, by a chip-on-plastic (COP) technique.

The circuit boards 300 may be on the display pads DP at one edge of the display panel 100. The circuit boards 300 may be attached to the display pads PD using a conductive adhesive member, such as an anisotropic conductive film and an anisotropic conductive adhesive. Accordingly, the circuit boards 300 may be electrically connected to signal lines of the display panel 100. The circuit boards 300 may be flexible printed circuit boards, flexible films, such as chip on films.

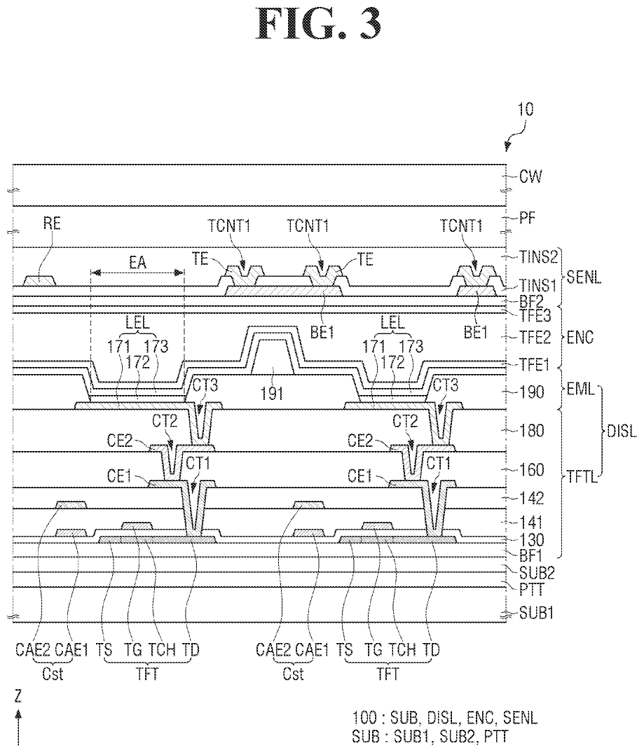

FIG. 3 is a cross-sectional view showing an example of the display area of the display device according to one or more embodiments of the present disclosure.

Referring to FIG. 3, the display device 10 may include a display panel 100, a polarizing film PF, and a cover window CW.

The display panel 100 may be an organic light-emitting display panel including light-emitting elements LEL each including an organic emissive layer 172. It should be understood, however, that the present disclosure is not limited thereto. The display panel 110 may be a light-emitting display panel, such as a quantum-dot light-emitting display panel including a quantum-dot emissive layer, an inorganic light-emitting display panel including an inorganic semiconductor, and a micro light-emitting display panel using micro or nano light-emitting diodes (micro LEDs or nano LEDs). In the following description, an organic light-emitting display panel is employed as an example of the display panel 100 for convenience of illustration.

The display panel 100 may include a substrate SUB, a display layer DISL, an encapsulation layer ENC, and a sensor electrode layer SENL.

The substrate SUB may include a first substrate SUB1, a protective layer PTT located on the first substrate SUB1, and a second substrate SUB2 located on the protective layer PTT.

The first substrate SUB1 may have a rigid material. For example, the first substrate SUB1 may be made of glass. The first substrate SUB1 may be formed of ultra-thin glass (UTG) having a thickness of about 500 μm or less.

The protective layer PTT may be located between the first substrate SUB1 and the second substrate SUB2. The protective layer PTT may have a thickness of about 0.1 μm or less. The protective layer PTT may include a material having higher adhesion to the first substrate SUB1 than to the second substrate SUB2. For example, the protective layer PTT may include silicon (Si).

According to one or more embodiments of the present disclosure, the protective layer PTT may include amorphous silicon (a-Si). According to one or more other embodiments, the protective layer PTT may include silicon oxide (SiOx). According to yet one or more other embodiments, the protective layer PTT may include at least one of amorphous silicon (a-Si) or silicon oxide (SiOx).

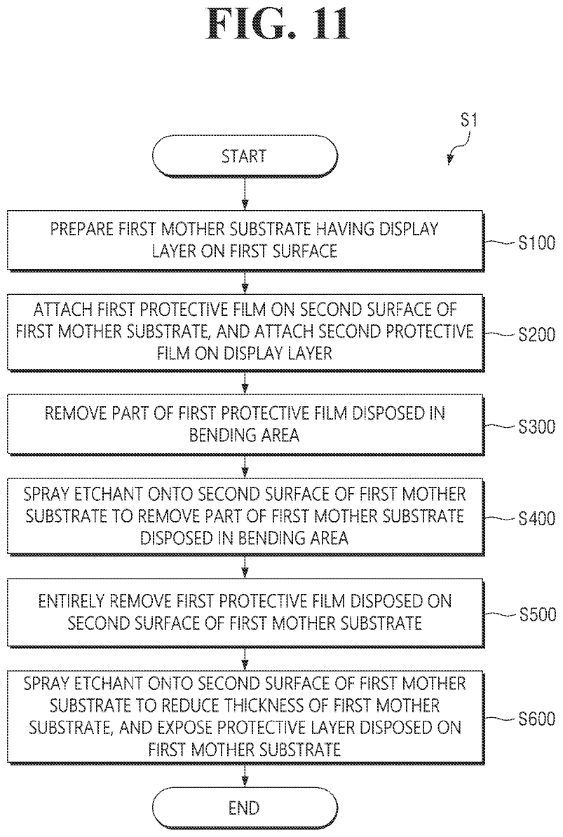

The protective layer PTT can reduce or prevent the formation of an undercut structure by reducing or preventing the likelihood of the first substrate SUB1 being overly etched during an etching process according to a method S1 of fabricating a display device described below (see FIG. 11). For example, the adhesive strength of the protective layer PTT to the first substrate SUB1 may be greater than the adhesive strength of the second substrate SUB2 to the first substrate SUB1. In addition, in an etching process of the method S1 of fabricating a display device (see FIG. 11) described below, the reactivity of the protective layer PTT to an etchant may be lower than that of the second substrate SUB2 to the etchant. Accordingly, it is possible to reduce or prevent the permeation of the etchant at the interface between the first substrate SUB1 and the protective layer PTT, thereby reducing or preventing the likelihood of an undercut from being formed.

The second substrate SUB2 may have a flexible material. The second substrate SUB2 may be made of a polymer resin having a thickness that is less than that of the first substrate SUB1. For example, the second substrate SUB2 may have a thickness of about 20 μm or less. The second substrate SUB2 may be formed of an organic material, such as an acryl resin, an epoxy resin, a phenolic resin, a polyamide resin, and a polyimide resin. In some embodiments, the second substrate SUB2 may have a multi-layer structure.

The display layer DISL may include a thin-film transistor layer TFTL including a plurality of thin-film transistors and an emission material layer EML including a plurality of light-emitting elements.

The thin-film transistor layer TFTL may include a first buffer film BF1, a thin-film transistor TFT, a gate insulator 130, a first interlayer dielectric film 141, a capacitor Cst, a second interlayer dielectric film 142, a first data metal layer, a first organic film 160, a second data metal layer, and a second organic film 180.

The first buffer film BF1 may be located on the substrate SUB. The first buffer film BF1 may be formed of an inorganic material, such as a silicon nitride layer, a silicon oxynitride layer, a silicon oxide layer, a titanium oxide layer, and/or an aluminum oxide layer. Alternatively, the first buffer film BF1 may be made up of multiple layers in which two or more of a silicon nitride layer, a silicon oxynitride layer, a silicon oxide layer, a titanium oxide layer, and/or an aluminum oxide layer are stacked on one another.

An active layer including a channel region TCH, a source region TS, and a drain region TD of the thin-film transistor TFT may be located on the first buffer film BF1. The active layer may be made of polycrystalline silicon, monocrystalline, low-temperature polycrystalline silicon, amorphous silicon, or an oxide semiconductor. When the active layer includes polycrystalline silicon or an oxide semiconductor material, the source region TS and the drain region TD in the active layer may be conductive regions doped with ions or impurities to have conductivity.

The gate insulator 130 may be located on the active layer of the thin-film transistor TFT. The gate insulator 130 may be formed of an inorganic layer, for example, a silicon nitride layer, a silicon oxynitride layer, a silicon oxide layer, a titanium oxide layer, or an aluminum oxide layer.

A first gate metal layer including a gate electrode TG of the thin-film transistor TFT, a first capacitor electrode CAE1 of a capacitor Cst, and scan lines may be located on the gate insulator 130. The gate electrode G of the thin-film transistor TFT may overlap the channel region TCH in the third direction (z-axis direction). The first gate metal layer may be made up of a single layer or multiple layers of one of molybdenum (Mo), aluminum (Al), chromium (Cr), gold (Au), titanium (Ti), nickel (Ni), neodymium (Nd), or copper (Cu) or an alloy thereof.

The first interlayer dielectric film 141 may be located on the first gate metal layer. The first interlayer dielectric film 141 may be formed of an inorganic layer, for example, a silicon nitride layer, a silicon oxynitride layer, a silicon oxide layer, a titanium oxide layer, or an aluminum oxide layer. The first interlayer dielectric film 141 may include a number of inorganic layers.

The second gate metal layer including a second capacitor electrode CAE2 of the capacitor Cst may be located on the first interlayer dielectric layer 141. The second capacitor electrode CAE2 may overlap the first capacitor electrode CAE1 in the third direction (z-axis direction). Therefore, the capacitor Cst may be formed by the first capacitor electrode CAE1, the second capacitor electrode CAE2, and an inorganic insulating dielectric film located therebetween and serving as a dielectric film. The second gate metal layer may be made up of a single layer or multiple layers of one of molybdenum (Mo), aluminum (Al), chromium (Cr), gold (Au), titanium (Ti), nickel (Ni), neodymium (Nd), or copper (Cu) or an alloy thereof.

A second interlayer dielectric film 142 may be located on the second gate metal layer. The second interlayer dielectric film 142 may be formed of an inorganic layer, for example, a silicon nitride layer, a silicon oxynitride layer, a silicon oxide layer, a titanium oxide layer, or an aluminum oxide layer. The second interlayer dielectric film 142 may include a number of inorganic layers.

The first data metal layer including first connection electrodes CE1 and data lines may be located on the second interlayer dielectric film 142. The first connection electrode CE1 may be connected to the drain region TD through a first contact hole CT1 penetrating the gate insulator 130, the first interlayer dielectric film 141, and the second interlayer dielectric film 142. The first data metal layer may be made up of a single layer or multiple layers of one of molybdenum (Mo), aluminum (Al), chromium (Cr), gold (Au), titanium (Ti), nickel (Ni), neodymium (Nd), or copper (Cu) or an alloy thereof.

A first organic film 160 may be located over the first connection electrode CE1 for providing a flat surface over the thin-film transistors TFT having uneven heights. The first organic film 160 may be formed as an organic layer, such as an acryl resin, an epoxy resin, a phenolic resin, a polyamide resin, and/or a polyimide resin.

A second data metal layer including second connection electrodes CE2 may be located on the first organic film 160. The second data metal layer may be connected to the first connection electrode CE1 through a second contact hole CT2 penetrating the first organic film 160. The second data metal layer may be made up of a single layer or multiple layers of one of molybdenum (Mo), aluminum (Al), chromium (Cr), gold (Au), titanium (Ti), nickel (Ni), neodymium (Nd), or copper (Cu) or an alloy thereof.

The second organic film 180 may be located on the second connection electrode CE2. The second organic film 180 may be formed as an organic layer, such as an acryl resin, an epoxy resin, a phenolic resin, a polyamide resin, and/or a polyimide resin.

It should be noted that the second data metal layer including the second connection electrodes CE2 and the second organic film 180 may be eliminated.

The emission material layer EML is located on the thin-film transistor layer TFTL. The emission material layer EML may include light-emitting elements LEL and a bank 190.

Each of the light-emitting elements LEL may include a pixel electrode 171, an emissive layer 172, and a common electrode 173. In each of the emission areas EA, the pixel electrode 171, the emissive layer 172, and the common electrode 173 are stacked on one another sequentially, so that holes from the pixel electrode 171 and electrons from the common electrode 173 are combined with each other in the emissive layer 172 to emit light. In such case, the pixel electrode 171 may be an anode electrode, while the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating the second organic film 180. The pixel electrode layer may be made up of a single layer or multiple layers of one of molybdenum (Mo), aluminum (Al), chromium (Cr), gold (Au), titanium (Ti), nickel (Ni), neodymium (Nd), or copper (Cu) or an alloy thereof.

In the top-emission structure, where light exits from the emissive layer 172 toward the common electrode 173, the pixel electrode 171 may be made up of a single layer of molybdenum (Mo), titanium (Ti), copper (Cu), or aluminum (Al), or may be made up of a stack structure of aluminum and titanium (Ti/Al/Ti), a stack structure of aluminum and ITO (ITO/AI/ITO), an APC alloy, or a stack structure of APC alloy and ITO (ITO/APC/ITO) to increase the reflectivity. The APC alloy is an alloy of silver (Ag), palladium (Pd), and copper (Cu).

The bank 190 may define the emission areas EA of the pixels. To this end, the bank 190 may be formed on the second organic film 180 to expose a portion of the pixel electrode 171. The bank 190 may cover the edge of the pixel electrode 171. The bank 190 may be partially located inside the third contact hole CT3. In other words, the third contact hole CT3 may be filled with the material of the bank 190. The bank 190 may be formed of an organic layer, such as an acryl resin, an epoxy resin, a phenolic resin, a polyamide resin, and a polyimide resin.

A spacer 191 may be located on the bank 190. The spacer 191 may support a mask during a process of fabricating the emissive layer 172. The spacer 191 may be formed of an organic layer, such as an acryl resin, an epoxy resin, a phenolic resin, a polyamide resin, and/or a polyimide resin.

The emissive layer 172 is formed on the pixel electrode 171. The emissive layer 172 may include an organic material to emit light of a certain color. For example, the emissive layer 172 may include a hole-transporting layer, an organic material layer, and an electron-transporting layer. The organic material layer may include a host and a dopant. The organic material layer may include a material that emits a light (e.g., predetermined light), and may be formed using a phosphor or a fluorescent material.

The common electrode 173 is formed on the emissive layer 172. The cathode electrode 173 may be formed to cover the emissive layer 172. The common electrode 173 may be a common layer formed across the emission areas EA. A capping layer may be formed on the common electrode 173.

In the top-emission structure, the common electrode 173 may be formed of a transparent conductive material (TCP), such as ITO and IZO that can transmit light, or a semi-transmissive conductive material, such as magnesium (Mg), silver (Ag), and/or an alloy of magnesium (Mg) and silver (Ag). When the common electrode 173 is formed of a semi-transmissive metal material, the light extraction efficiency can be increased by using microcavities.

The encapsulation layer ENC may be located on the emission material layer EML. The encapsulation layer ENC may include one or more inorganic films TFE1 and TFE3 to reduce or prevent permeation of oxygen or moisture into the emission material layer EML. In addition, the encapsulation layer ENC may include at least one organic film to protect the emission material layer EML from particles, such as dust. For example, the encapsulation layer ENC may include a first inorganic encapsulation film TFE1, an organic encapsulation film TFE2, and a second inorganic encapsulation film TFE3.

The first inorganic encapsulation film TFE1 may be located on the common electrode 173, the organic encapsulation film TFE2 may be located on the first inorganic encapsulation film TFE1, and the second inorganic encapsulation film TFE3 may be located on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer, and/or an aluminum oxide layer are alternately stacked on one another. The organic encapsulation film TFE2 may be an organic film, such as an acryl resin, an epoxy resin, a phenolic resin, a polyamide resin, a polyimide resin, etc.

The sensor electrode layer SENL may be located on the encapsulation layer ENC. The sensor electrode layer SENL may include a second buffer film BF2, a first bridge BE1, a first sensor insulating film TINS1, sensor electrodes TE and RE, and a second sensor insulating film TINS2.

A second buffer film BF2 may be located on the encapsulation layer ENC. The second buffer film BF2 may include at least one inorganic film. For example, the second buffer film BF2 may be made up of multiple layers in which one or more inorganic layers of a silicon nitride layer, a silicon oxynitride layer, a silicon oxide layer, a titanium oxide layer, and/or an aluminum oxide layer are alternately stacked on one another. The second buffer film BF2 may be omitted in one or more other embodiments.

First bridges BE1 may be located on the second buffer film BF2. The first bridges BE1 may be made up of a single layer of molybdenum (Mo), titanium (Ti), copper (Cu), or aluminum (Al), or may be made up of a stack structure of aluminum and titanium (Ti/Al/Ti), a stack structure of aluminum and ITO (ITO/AI/ITO), an APC alloy, or a stack structure of an APC alloy and ITO (ITO/APC/ITO).

A first sensor insulating film TINS1 may be located on the first bridges BE1. The first sensor insulating film TINS1 may be formed of an inorganic layer, for example, a silicon nitride layer, a silicon oxynitride layer, a silicon oxide layer, a titanium oxide layer, or an aluminum oxide layer.

The sensor electrodes (e.g., driving electrodes TE and sensing electrodes RE) may be located on the first sensor insulating film TINS1. In addition, dummy patterns may be located on the first sensor insulating film TNIS1. The driving electrodes TE, the sensing electrodes RE, and the dummy patterns do not overlap the emission areas EA. The driving electrodes TE, the sensing electrodes RE, and the dummy patterns may be made up of a single layer of molybdenum (Mo), titanium (Ti), copper (Cu), or aluminum (Al), or may be made up of a stack structure of aluminum and titanium (Ti/Al/Ti), a stack structure of aluminum and ITO (ITO/AI/ITO), an APC alloy, or a stack structure of an APC alloy and ITO (ITO/APC/ITO).

The second sensor insulating film TINS2 may be located on the driving electrodes TE, on the sensing electrodes RE, and on the dummy patterns. The second sensor insulating film TINS2 may include at least one of an inorganic film or an organic film. The inorganic film may be a silicon nitride layer, a silicon oxynitride layer, a silicon oxide layer, a titanium oxide layer, or an aluminum oxide layer. The organic film may be an acryl resin, an epoxy resin, a phenolic resin, a polyamide resin, or a polyimide resin.

The polarizing film PF may be located on the sensor electrode layer SENL. The polarizing film PF may be located on the display panel 100 to reduce reflection of external light. The polarizing film PF may include a first base member, a linear polarizer, a retardation film, such as a λ/4 (quarter-wave) plate, and a second base member. The first base member, the retardation film, the linear polarizer and the second base member of the polarizing film PF may be sequentially stacked on the display panel 100.

The cover window CW may be located on the polarizing film PF. The cover window CW may be attached onto the polarizing film PF by a transparent adhesive member, such as an optically clear adhesive (OCA) film.

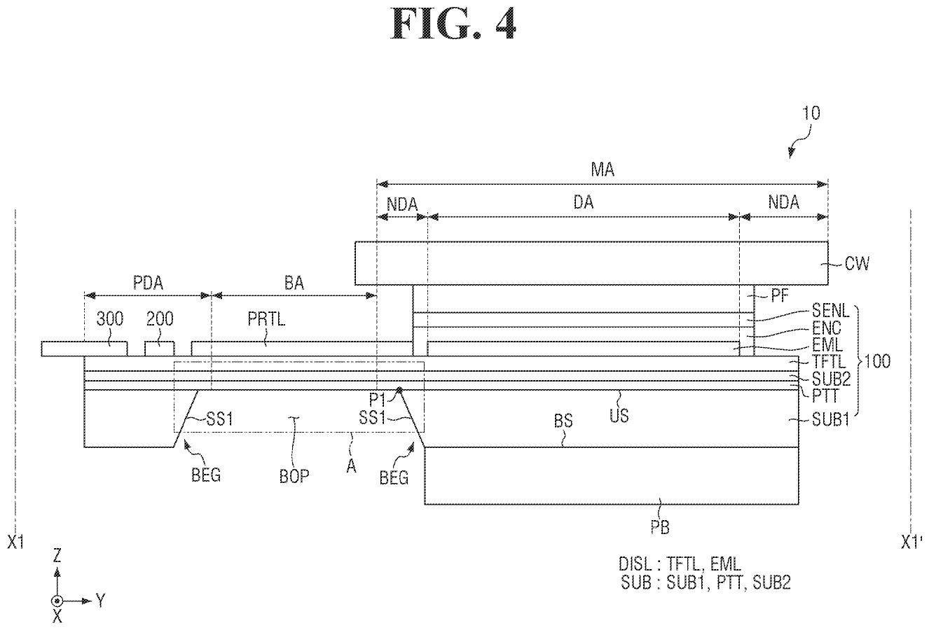

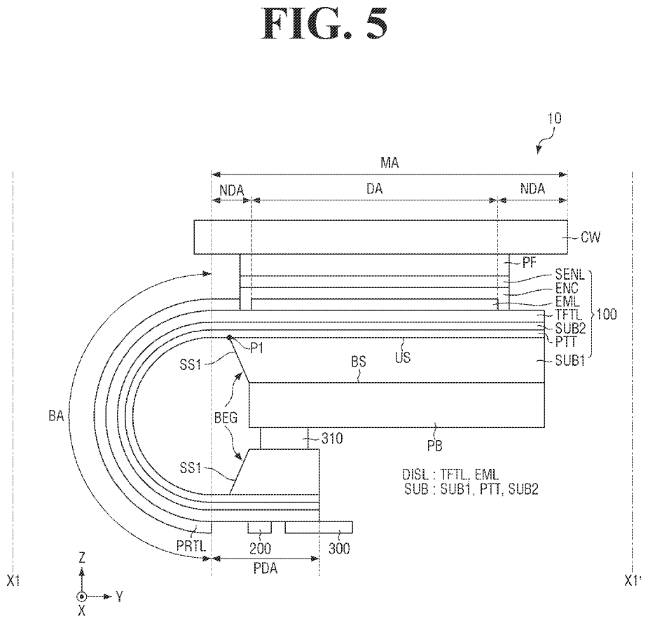

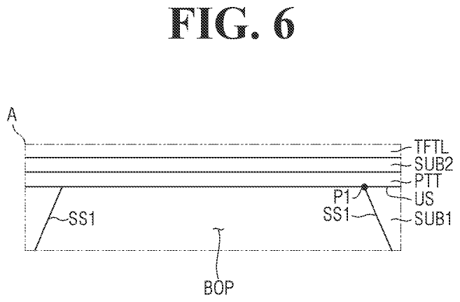

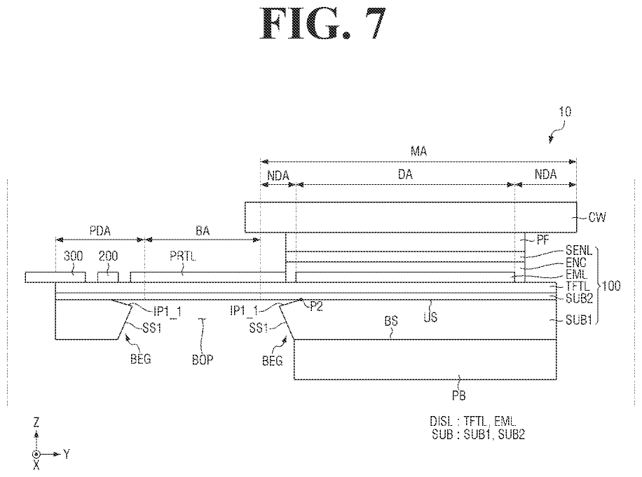

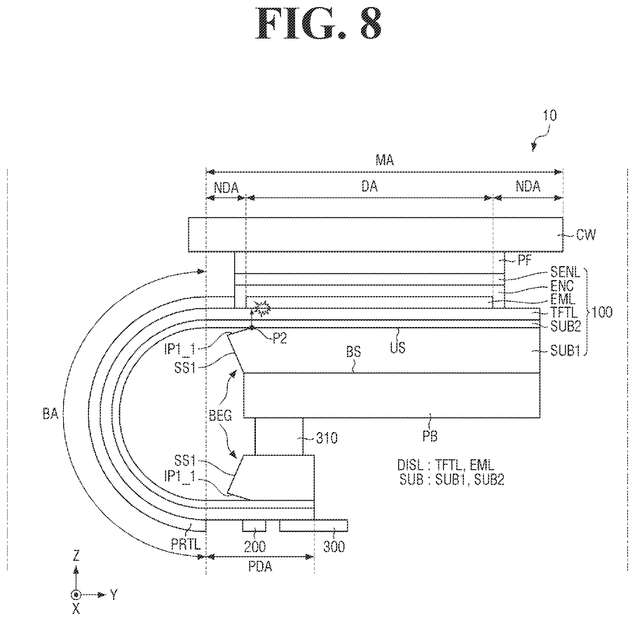

FIG. 4 is a cross-sectional view taken along the line X1-X1′ in FIG. 1. FIG. 5 is a cross-sectional view showing the display device according to the one or more embodiments corresponding to FIG. 4 when it is bent. FIG. 6 is an enlarged view of portion A of FIG. 4. FIG. 7 is a cross-sectional view schematically showing an existing display device. FIG. 8 is a cross-sectional view showing the existing display device of FIG. 7 when it is bent.

Referring to FIGS. 4 to 8, the display device 10 may further include a protective film PRTL and a panel bottom cover PB, in addition to the display panel 100, the polarizing film PF, the cover window CW, the driver IC 200, and the circuit board 300. The display panel 100 may include a substrate SUB, a display layer DISL, an encapsulation layer ENC, and a sensor electrode layer SENL.

The display layer DISL, the encapsulation layer ENC, the sensor electrode layer SENL, the polarizing film PF, and the cover window CW have been described above, and redundant descriptions thereof will be omitted.

The substrate SUB may include a first substrate SUB1, a protective layer PTT located on the first substrate SUB1, and a second substrate SUB2 located on the protective layer PTT.

The first substrate SUB1 may not be located in the bending area BA. For example, the first substrate SUB1 may include, or define, an opening BOP exposing the protective layer PTT. That is to say, because the first substrate SUB1 made of a rigid material is not located in the bending area BA, it can be easily bent as shown in FIG. 5.

The protective film PRTL may be located on the thin-film transistor layer TFTL in the bending area BA. The protective film PRTL may be a layer for protecting the thin-film transistor layer TFTL exposed to the outside in the bending area BA. The protective film PRTL may be formed of an organic material, such as an acryl resin, an epoxy resin, a phenolic resin, a polyamide resin, and/or a polyimide resin.

The panel bottom cover PB may be located on a second surface (e.g., bottom surface) of the substrate SUB of the display panel 100. The second surface of the substrate SUB may be opposite to the first surface. The panel bottom cover PB may be attached to the second surface of the substrate SUB of the display panel 100 by an adhesive member. The adhesive member may be a pressure-sensitive adhesive (PSA).

The panel bottom cover PB may include at least one of a light-blocking member for absorbing light incident from outside, a buffer member for absorbing external impact, or a heat-dissipating member for efficiently discharging heat from the display panel 100.

The driver IC 200 and the circuit board 300 may be bent such that they are located under the display panel 100, as shown in FIG. 5. The circuit board 300 may be attached to the lower surface of the panel bottom cover PB by an adhesive member 310. The adhesive member 310 may be a pressure-sensitive adhesive.

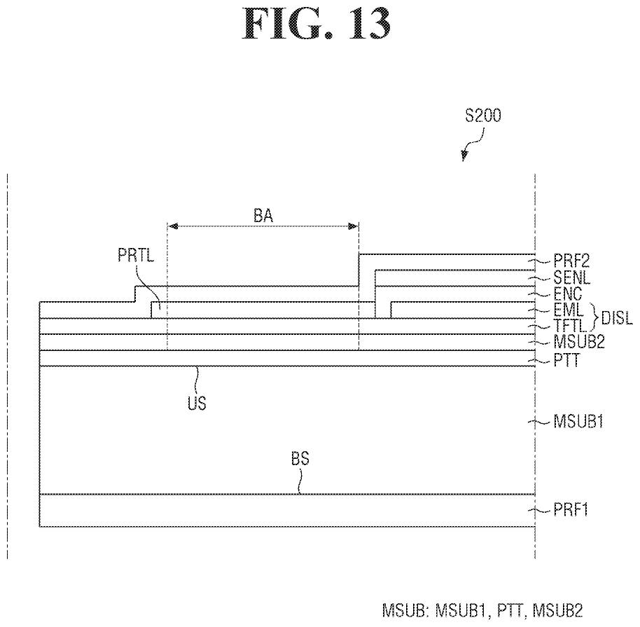

The presently described display device 10 may include a first side surface SS1 at an edge BEG of the bending area BA. The first side surface SS1 formed at the edge BEG of the bending area BA may be an inclined surface. The inclined surface of the first side surface SS1 may be formed by attaching a first protective film PRF1 (see FIG. 13) to etch a part of the first substrate SUB1 on the bending area BA according to the method S1 of fabricating a display device to be described later (see FIG. 11). The edge BEG of the bending area BA may refer to an edge formed by etching the first substrate SUB1 on the bending area BA according to the method S1 of fabricating a display device (see FIG. 11).

For example, the first substrate SUB1 may include an upper surface US, a lower surface BS, and a first side surface SS1. The upper surface US of the first substrate SUB1 may be a side surface in the third direction (z-axis direction), and the lower surface BS may be the opposite side surface in the third direction (z-axis direction).

The first side surface SS1 may be located between the upper surface US and the lower surface BS. The first side surface SS1 may be positioned at the edge BEG of the bending area BA. The first side surface SS1 may be an inclined surface. According to one or more embodiments of the present disclosure, the angle formed between the first side surface SS1 and the upper surface US may be an acute angle, and the angle formed between the first side surface SS1 and the lower surface BS may be an obtuse angle.

The first side surface SS1 and the upper surface US may be directly connected with each other. For example, an inclined surface extended in a direction different from the directions in which the first side surface SS1 and the upper surface US extend might not be located between the first side surface SS1 and the upper surface US (e.g., there might be no additional inclined surface).

The entire upper surface US of the first substrate SUB1 may be in direct contact with the protective layer PTT. There may be no gap between the upper surface US of the first substrate SUB1 and the protective layer PTT.

The protective layer PTT in the presently described display device 10 can reduce or prevent the formation of an undercut structure by reducing or preventing the likelihood of the first substrate SUB1 being overly etched during an etching process according to the method S1 of fabricating a display device described below (see FIG. 11). For example, the adhesive strength of the protective layer PTT to the first substrate SUB1 may be greater than the adhesive strength of the second substrate SUB2 to the first substrate SUB1. In addition, in an etching process of the method S1 of fabricating a display device (see FIG. 11) described below, the reactivity of the protective layer PTT to an etchant may be lower than that of the second substrate SUB2 to the etchant. Accordingly, it is possible to reduce or prevent the permeation of the etchant at the interface between the first substrate SUB1 and the protective layer PTT, thereby reducing or preventing the likelihood of an undercut being formed.

As shown in FIGS. 7 and 8, in the existing display device, the second substrate SUB2 may be located directly on the first substrate SUB1. Because the adhesive strength between the first substrate SUB1 and the second substrate SUB2 is relatively weak, an etchant may permeate into the interface between the first substrate SUB1 and the second substrates SUB2 during an etching process according to the method S1 of fabricating a display device described later (see FIG. 11). Accordingly, a first inclined surface IP1_1 may be formed between the first side surface SS1 and the upper surface US.

In contrast, the presently described display device 10 further includes the protective layer PTT having stronger adhesive strength to the first substrate SUB1 between the first substrate SUB1 and the second substrate SUB2, so that it is possible to reduce or prevent an undercut, such as the inclined surface IP1_1. As a result, no gap can be formed between the first substrate SUB1 and the second substrate SUB2, and thus it is possible to reduce or prevent the likelihood of delamination of the second substrate SUB2.

In addition, in the existing display device, a boundary P2 where the first inclined surface IP1_1 meets the second substrate SUB2 may overlap the display area DA in the third direction (z-axis direction). In contrast, in the presently described display device 10, the boundary P1 where the first side surface SS1 meets the protective layer PTT may not overlap with the display area DA.

For example, in the presently described display device 10, an undercut, such as the first inclined surface IP1_1 can be reduced or prevented, so that it is possible to reduce or prevent the likelihood of cracks in the inorganic films inside the display layer DISL, which may otherwise occur in the display device 10 where the first inclined surface IP1_1 overlaps with the display area DA in the third direction (z-axis direction) when the display device 10 is bent.

Hereinafter, display devices according to other embodiments of the present disclosure will be described. In the following description, the same or similar elements will be denoted by the same or similar reference numerals, and redundant descriptions will be omitted or briefly described.

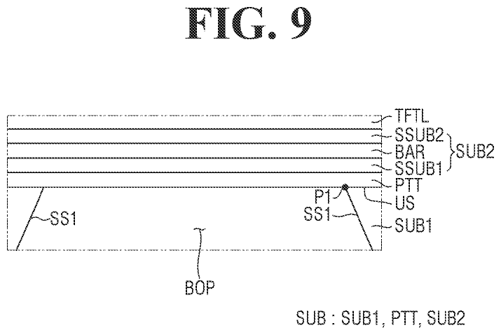

FIG. 9 is an enlarged, cross-sectional view showing a part of a display device according to one or more other embodiments of the present disclosure.

A display device 10 according to the one or more embodiments corresponding to FIG. 9 is different from the display device 10 according to the one or more embodiments corresponding to FIG. 8 and the like in that a second substrate SUB2 has a multi-layer structure.

For example, the second substrate SUB2 may include a first subsidiary substrate SSUB1, a barrier layer BAR, and a second subsidiary substrate SSUB2.

The first subsidiary substrate SSUB1 may be located on a protective layer PTT. The second subsidiary substrate SSUB2 may be located on a barrier layer BAR. The first subsidiary substrate SSUB1 and the second subsidiary substrate SSUB2 may have a flexible material. The second substrate SUB2 may be made of a polymer resin having a thickness that is less than that of the first substrate SUB1. For example, the second substrate SUB2 may be formed of an organic material, such as an acryl resin, an epoxy resin, a phenolic resin, a polyamide resin, or a polyimide resin.

The barrier layer BAR may be located between the first subsidiary substrate SSUB1 and the second subsidiary substrate SSUB2. The barrier layer BAR may include an inorganic insulating material. Accordingly, the barrier layer BAR can reduce or prevent impurities, such as moisture from permeating into the second subsidiary substrate SSUB2 through the first sub-substrate SSUB1 from the outside. The barrier layer BAR may include at least one of silicon oxide (SiOx), silicon nitride (SiNx), silicon oxynitride (SiOxNy), silicon oxycarbide (SiOxCy), silicon carbonitride (SiCxNy), aluminum oxide (AlxOy), aluminum nitride (AlxNy), tantalum oxide (TaxOy), hafnium oxide (HfxOy), zirconium oxide (ZrxOy), or titanium oxide (TixOy).

In some embodiments, the barrier layer BAR may include the same material as the protective layer PTT. For example, the barrier layer BAR may include at least one of amorphous silicon or silicon oxide (SiOx).

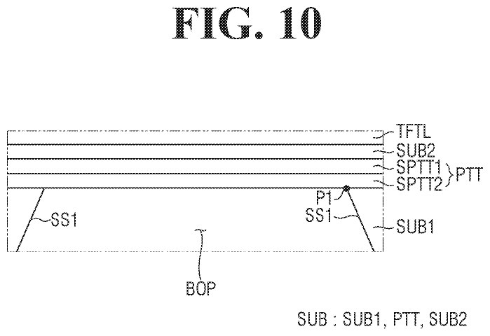

FIG. 10 is an enlarged cross-sectional view showing a part of a display device according to yet one or more other embodiments of the present disclosure.

A display device 10 according to the one or more embodiments corresponding to FIG. 10 is different from the display device 10 described above with reference to FIG. 8 and the like in that a protective layer PTT has a multi-layer structure.

For example, the protective layer PTT may include a first protective layer SPTT1 and a second protective layer SPTT2.

The first protective layer SPTT1 may include silicon oxide (SiOx). The second protective layer SPTT2 may include amorphous silicon. In some embodiments, and for example, the first protective layer SPTT1 may be formed by plasma treatment using a gas containing oxygen atoms in an amorphous silicon layer, but the present disclosure is not limited thereto.

The hydrophilic property of the first protective layer SPTT1 can be improved by plasma treatment, and thus the adhesive strength between the first protective layer SPTT1 and the first substrate SUB1 can be enhanced. Accordingly, it is possible to further suppress the etchant from permeating into the interface between the first substrate SUB1 and the protective layer PTT, thereby reducing or preventing the formation of an undercut.

Hereinafter, a method of fabricating a display device according to one or more embodiments of the present disclosure will be described.

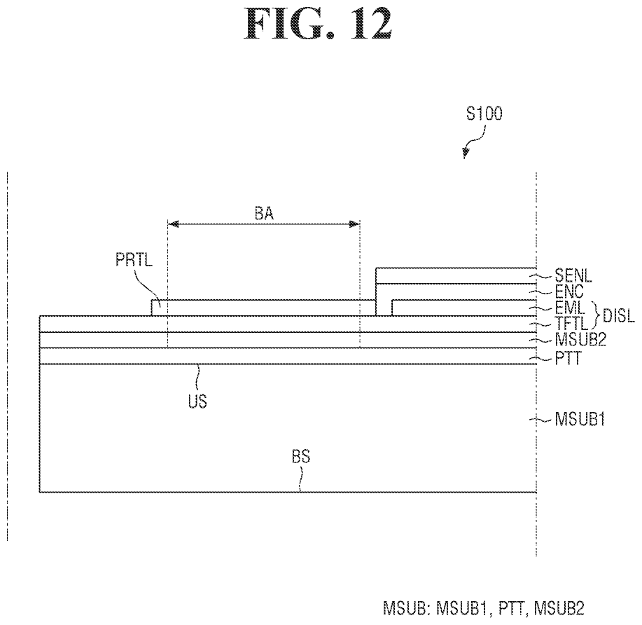

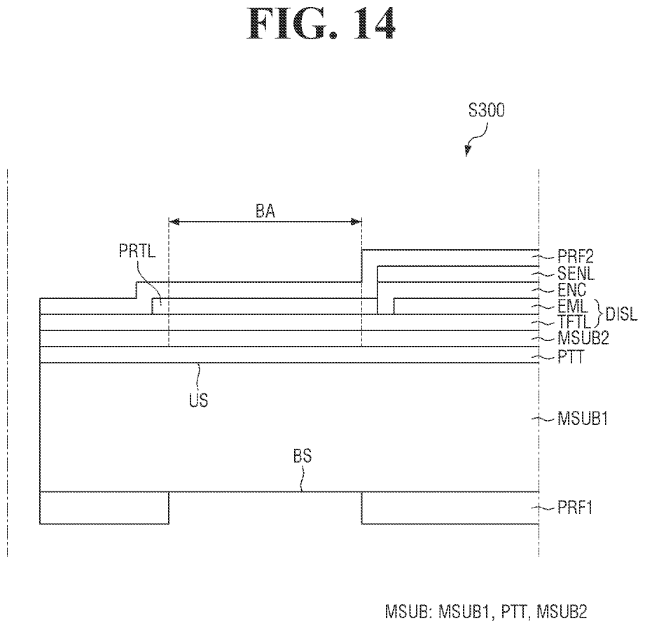

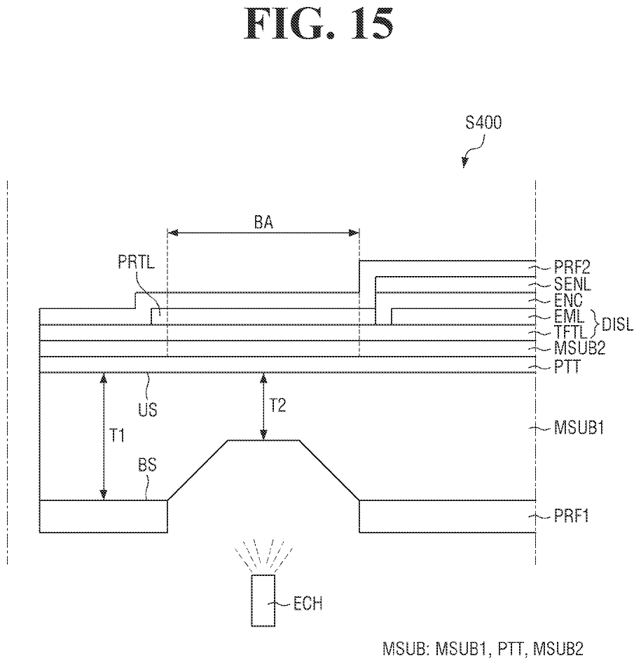

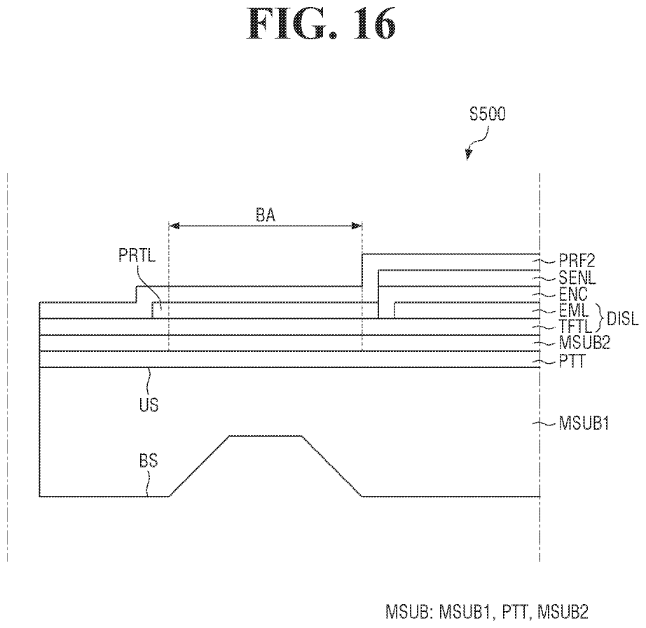

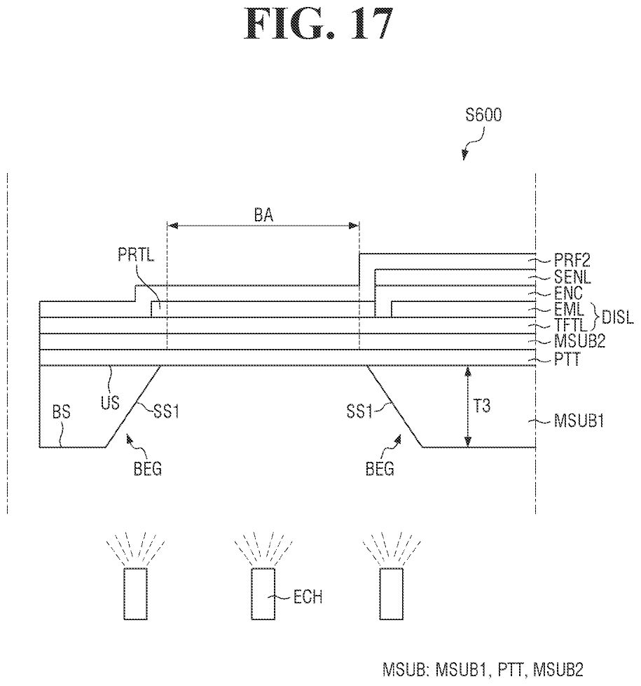

FIG. 11 is a flowchart for illustrating a method of fabricating a display device according to one or more embodiments of the present disclosure. FIG. 12 is a cross-sectional view showing operation S100 of FIG. 11. FIG. 13 is a cross-sectional view showing operation S200 of FIG. 11. FIG. 14 is a cross-sectional view showing operation S300 of FIG. 11. FIG. 15 is a cross-sectional view showing operation S400 of FIG. 11. FIG. 16 is a cross-sectional view showing operation S500 of FIG. 11. FIG. 17 is a cross-sectional view showing operation S600 of FIG. 11.

Referring to FIGS. 11 to 17, the method S1 of fabricating a display device according to one or more embodiments may include, first, forming a display layer DISL on an upper surface US of a first mother substrate MSUB1 (operation S100 of FIG. 11), as shown in FIG. 12.

For example, a mother substrate MSUB may include the first mother substrate MSUB1, a protective layer PTT, and a second mother substrate MSUB2. The protective layer PTT may be formed on the upper surface US of the first mother substrate MSUB1, and the second mother substrate MSUB2 may be formed on the protective layer PTT.

Subsequently, the display layer DISL may be formed on the second mother substrate MSUB2, and an encapsulation layer ENC and a sensor electrode layer SENL may be further formed.

Second, as shown in FIG. 13, a first protective film PRF1 may be attached on a lower surface BS of the first mother substrate MSUB1, and a second protective film PRF2 may be attached on the display layer DISL (operation S200 of FIG. 11).

For example, the first protective layer PRF1 may be attached to the entire lower surface BS of the first mother substrate MSUB1. When the encapsulation layer ENC and the sensor electrode layer SENL are located on the display layer DISL, the second protective layer PRF2 may be attached on the sensor electrode layer SENL. The second protective layer PRF2 may cover the display layer DISL, the encapsulation layer ENC, and the sensor electrode layer SENL altogether.

The first protective layer PRF1 and the second protective layer PRF2 may be acid-resistant films. The first protective layer PRF1 can reduce or prevent the likelihood of the first mother substrate MSUB1 being etched where the first protective layer PRF1 is attached. The second protective layer PRF2 can protect the display layer DISL from an etchant ECH (see FIG. 15).

Thirdly, as shown in FIG. 14, a portion of the first protective layer PRF1 located in a bending area BA may be removed (operation S300 of FIG. 11).

A portion of the lower surface BS of the first mother substrate MSUB1 may be exposed in the bending area BA where the first protective layer PRF1 is removed.

Fourthly, as shown in FIG. 15, the etchant ECH is sprayed on the lower surface BS of the first mother substrate MSUB1 so that the first mother substrate MSUB1 located in the bending area BA may be partially removed (operation S400 in FIG. 11).

As a portion of the first mother substrate MSUB1 is removed in the bending area BA, there may be differences in thickness between the etched area and the non-etched area. For example, a second thickness T2 of the first mother substrate MSUB1 in the bending area BA may be less than a first thickness T1 of the first mother substrate MSUB1 in the other area than the bending area BA. The second thickness T2 may be about 0.5 times to about 0.7 times the first thickness T1.

After a portion of the first mother substrate MSUB1 is etched, inclined surfaces may be formed in the bending area BA. Such inclined surfaces may be formed by isotropic nature of wet etching.

Fifthly, as shown in FIG. 16, the entirety of the first protective layer PRF1 located on the lower surface BS of the first mother substrate MSUB1 may be removed. Accordingly, the entire lower surface BS of the first mother substrate MSUB1 may be exposed (operation S500 of FIG. 11).

Sixthly, as shown in FIG. 17, the overall thickness of the first mother substrate MSUB1 may be reduced by spraying the etchant ECH onto the lower surface BS of the first mother substrate MSUB1, and the protective layer PTT located on the first mother substrate MSUB1 may be exposed (operation S600 of FIG. 11).

By spraying the etchant onto the lower surface BS of the first mother substrate MSUB1, the first thickness T1 of the first mother substrate MSUB1 can be reduced to the third thickness T3. The first thickness T1 may be about 500 μm, and the third thickness T3 may be about 200 μm, but the present disclosure is not limited thereto.

Because the first mother substrate MSUB1 is etched without any mask, the entire lower surface BS of the first mother substrate MSUB1 can be etched substantially uniformly (isotropic etch). As a result, the first side surface SS1 may be formed as an inclined surface at the edge BEG of the first substrate MSUB1 in the bending area BA along the inclined surface formed in operation S400.

As the thickness of the first mother substrate MSUB1 decreases, a portion of the first mother substrate MSUB1 that is located at the bending area BA may be completely etched, and thus the protective layer PTT may be exposed. Even after the protective layer PTT is exposed, the first mother substrate MSUB1 may be overly etched to completely remove the first mother substrate MSUB1 located in the bending area BA. At this time, because the adhesive strength between the protective layer PTT and the first mother substrate MSUB1 is relatively strong, the etchant ECH cannot permeate into the interface between the protective layer PTT and the first mother substrate MSUB1. In this manner, in the display device 10 according to this embodiment, it is possible to reduce or prevent the likelihood of an undercut being formed at the interface between the protective layer PTT and the first mother substrate MSUB1.

In concluding the detailed description, those skilled in the art will appreciate that many variations and modifications can be made to the embodiments without substantially departing from the aspects of the present disclosure. Therefore, the disclosed embodiments of the disclosure are used in a generic and descriptive sense only and not for purposes of limitation.

What is claimed is:

1. A display device comprising:
a first substrate comprising a rigid material, and comprising a first surface, a second surface opposite to the first surface, and a first side surface between the first surface and the second surface;
a protective layer on the first surface;
a second substrate comprising a flexible material on the protective layer; and
an emission material layer comprising light-emitting elements on the second substrate.

2. The display device of claim 1, wherein the first side surface is at an edge in a bending area where the second substrate is bent.

3. The display device of claim 2, wherein the first substrate is not in the bending area.

4. The display device of claim 2, wherein the first substrate defines an opening exposing the protective layer in the bending area.

5. The display device of claim 1, wherein the first side surface is an inclined surface extending in a direction that is different from a direction in which the first surface extends.

6. The display device of claim 1, wherein an entirety of the first surface directly contacts the protective layer.

7. The display device of claim 6, wherein the first surface and the first side surface directly contact each other.

8. The display device of claim 7, wherein an inclined surface extending in a direction that is different from directions in which the first surface and the first side surface extend is not between the first surface and the first side surface.

9. The display device of claim 1, wherein a boundary where the first side surface meets the protective layer does not overlap with a display area in which the light-emitting elements are located.

10. The display device of claim 1, wherein the first substrate comprises glass, and
wherein the second substrate comprises a polymer resin.

11. The display device of claim 1, wherein an adhesive strength of the protective layer to the first substrate is higher than an adhesive strength of the second substrate to the first substrate.

12. The display device of claim 1, wherein the protective layer comprises silicon.

13. The display device of claim 12, wherein the protective layer comprises amorphous silicon or silicon oxide (SiOx).

14. The display device of claim 1, wherein the protective layer has a thickness of about 0.1 μm or less.

15. The display device of claim 1, wherein the second substrate comprises:
a first subsidiary substrate on the protective layer;
a barrier layer on the first subsidiary substrate; and
a second subsidiary substrate on the barrier layer.

16. The display device of claim 15, wherein the barrier layer and the protective layer comprise a same material.

17. The display device of claim 1, wherein the protective layer comprises:
a first protective layer comprising silicon oxide (SiOx) on the first substrate; and
a second protective layer comprising amorphous silicon on the first protective layer.

18. A method of fabricating a display device, the method comprising:
preparing a first mother substrate having a first surface, and a second surface opposite to the first surface, a protective layer on the first surface, a second mother substrate on the protective layer, and a display layer on the second mother substrate;
attaching a first protective film on the second surface;
removing a portion of the first protective film from a bending area;
removing a portion of the first mother substrate from the bending area by spraying an etchant onto the second surface;
entirely removing the first protective film on the second surface; and
exposing the protective layer by spraying an etchant onto the second surface to reduce a thickness of the first mother substrate.

19. The method of claim 18, wherein, in the exposing the protective layer, an entirety of the first surface is in direct contact with the protective layer.

20. The method of claim 18, wherein the protective layer comprises silicon.
